(19) United States
(12) Patent Application Publication
(10) Pub. No.: US 2011/0269089 A1
(43) Pub. Date: Nov. 3, 2011

(54) HEAT TREATMENT APPARATUS FOR SOLAR CELLS

(75) Inventors: Takeshi Echizenya, Tochigi (JP); Yuichi Hirano, Tochigi (JP); Hitoshi Nagasaki, Tochigi (JP); Yoshinori Tokunaga, Tochigi (JP); Satoshi Yonezawa, Tochigi (JP)

(73) Assignee: HONDA MOTOR CO., LTD, Minato-ku, Tokyo (JP)

(21) Appl. No.: 12/937,963

(22) PCT Filed: Apr. 14, 2009
(86) PCT No.: PCT/JP2009/001715

§ 371 Date: Oct. 14, 2010

(30) Foreign Application Priority Data
Apr. 17, 2008 (JP) 2008-108010

(51) Int. Cl. H01L 31/18; F27D 1/00; F27B 5/14

(52) U.S. Cl. 432/221; 432/247

(57) ABSTRACT

A heat treatment apparatus for a selenization process or a sulphurization process carried out when forming a light absorbing layer in a chalcopyrite-type solar cell, comprises a quartz tube in which a plurality of solar cell substrates is arranged in parallel at predetermined intervals in a thickness direction, a heating mechanism for heating atmospheric gas, which is arranged at an outside of the quartz tube, and first baffle plates arranged upward of the substrates, in which heated atmospheric gas, which rises along an inner surface of the quartz tube, is guided from upward to the center of the substrates.

### TECHNICAL FIELD

The present invention relates to a heat treatment apparatus for chalcopyrite-type solar cells, used in a production method for thin film solar cells, in particular, in a selenization process during formation of a light absorbing layer.

### BACKGROUND ART

The chalcopyrite-type thin film solar cell is of the thin film type, and it has a CIGS layer comprising a chalcopyrite compound, in which an element thereof is in group I, group III, or group VI, as a p-type light absorbing layer. The chalcopyrite-type thin film solar cell has a multilayer structure in which a back surface electrode layer acts as a cathode which is a Mo metal layer, a CIGS light absorbing layer, an n-type buffer layer, and a frontmost layer as an anode which is a transparent electrode layer are laminated on a glass substrate.

Then, when irradiated light such as sunlight is emitted from a surface receiver of this multilayer structure, a pair of an electron and a positive hole is excited by the irradiation light having energy over a band gap near a p-n junction in the multilayer structure. The excited electron and the positive hole reach the p-n junction by diffusion, and the electron and the positive hole are locally separated to an n-region and a p-region, respectively, by the internal electrical field of the junction. As a result, the n-region is negatively charged, and the p-region is positively charged, and a potential difference is generated between the electrodes provided on each region. When these electrodes are connected by a conducting wire, a photocurrent is obtained by electromotive force due to this potential difference, and this is the principle of the solar cell.

As a production method for a CIGS light absorbing layer in such a thin film solar cell, a method comprising a precursor forming process in which a precursor including Cu, In, and Ga, is formed on a back surface electrode layer formed on a substrate by sputtering, etc., and a selenization process in which a light absorbing layer is formed by heat-treating the precursor formed substrate under a selenization gas (H₂Se, hydrogen selenide gas) atmosphere, may be mentioned (see Patent Publication 1). In the case in which the selenization is carried out by using this method, a plurality of the above substrates is disposed in the apparatus and the inside of the apparatus is replaced with an inert gas such as nitrogen gas, and then, a selenium source is inserted and sealed, and the substrates are heated under this condition to a predetermined temperature for a predetermined time, and thereby, the light absorbing layer is formed.

However, in this method, since a plurality of the substrates is arranged and heated from side surfaces or circumference of the substrates, there are problems in that (1) the heating may be insufficient depending to the arrangement of the substrate and (2) the constituent ratio thereof is not uniform, and therefore, a homogeneous CIGS light absorbing layer is not formed (a) on every the substrate or (b) in the surface of the substrate, and therefore, solar cell characteristics are not uniform.

The above problems will be explained in more detail, and the problem (1) is described as follows. The circumference of a plurality of the filled substrates is heated primarily by radiation, and a surface of the substrate that is the outermost has superior temperature distribution since uniform heat radiation is received from a heat source. However, the radiation from the heat source is mostly absorbed by a precursor formed on the substrate arranged at the outermost side. As a result, the substrates arranged from the second outermost to the center are heated primarily by heat conduction in the substrate and convection of atmospheric gas that flows on the surface of the substrate. In this case, the heat conduction has a temperature distribution determined by each peculiar physical property of the precursor and the substrates, and the atmospheric gas has its own temperature distribution in the apparatus, and therefore, (a) the overall temperature of the center of the substrate is lower than that of the outside thereof and moreover, (b) the temperature uniformity on the surface of the substrate is inferior.

In addition, the problem (2) is described as follows. Hydrogen selenide gas introduced into the apparatus is decomposed into hydrogen and selenium molecule when it is heated at about 160° C., and this selenium molecule is taken in a layer by contacting a heated precursor surface. In this reaction process, in the case in which the temperature of all substrates in the apparatus is uniform, the selenization gas in the apparatus is uniformly circulated on each substrate surface, and a homogeneous light absorbing layer is formed by uniformly contacting the selenization gas with the substrate surface. However, the temperature difference occurs in every the substrate as explained in (1), and in addition, an updraft is generated between the substrate and the quartz tube by the selenization gas heated in the apparatus; however, some of the heated selenization gas falls from the clearances between each substrate during rising and another part remains at an upper portion of the substrates without falling through the substrates, after it rises to the upper portion of the substrates. Therefore, circulation of the atmospheric gas on the surface of the substrates is not made uniform and as a result, (b) constituents on the substrates are not uniform.

As a technique for solving such a problem, a method in which atmospheric gas is forcibly circulated by providing an electromotive fan in a reactor, (see Patent Publication 2) may be mentioned. Generally, a selenization process or a sulphurization process at about 650° C. are required in order to produce the substrates in the chalcopyrite-type solar cell. In addition, it is necessary that material of the reactor used in such a process have selenium resistance at high temperatures.

However, in the case in which an electromotive fan is used, it is necessary that the material of the fan have selenium corrosion resistance, and it is also necessary that it have seal durability of the rotating shaft, in particular, durability in view of processing temperature, friction heat, corrosion gas, etc.

Patent Publication 1 is Japanese Unexamined Patent Application Publication No. 2006-196771. Patent Publication 2 is Japanese Unexamined Patent Application Publication No. 2006-186114.

### DISCLOSURE OF THE INVENTION

### Problems Solved by the Invention

Therefore, the present invention was completed in view of the above-described circumstances, and an object of the present invention is to provide a heat treatment apparatus for chalcopyrite-type solar cells in which a CIGS light absorbing layer having high quality can be obtained by promoting uniformity of temperature in the apparatus and uniformity of atmospheric circulation.

### Means for Solving the Problems

The heat treatment apparatus of the present invention is a heat treatment apparatus for a selenization process or a sulphurization process carried out when forming a light absorbing layer in a chalcopyrite-type solar cell, and it comprises of a quartz tube in which a plurality of solar cell substrates is arranged in a parallel manner at predetermined intervals in a thickness direction therein, a heating mechanism for heating atmospheric gas, which is arranged outside of the quartz tube, and first baffle plates arranged upward of the substrates, in which heated atmospheric gas, which rises along an inner surface of the quartz tube, is guided from upward to the center of the substrates.

According to the present invention, convection of the atmospheric gas is promoted by a simple composition, and heated gas is reliably guided even to the center of the substrates, at which it is easy for gas temperature to decrease, and as a result, differences in temperature between the substrates is reduced, a CIGS light absorbing layer having high quality is formed, and therefore, improvement and uniformity of performance of the solar cell can be carried out. In addition, according to the heat treatment apparatus for chalcopyrite-type solar cells of the present invention, reliability over a long term can be improved, since a simple composition having no drive mechanism is realized.

### BRIEF DESCRIPTION OF THE DRAWINGS

FIG. 1 is a vertical front cross section schematically showing an embodiment of a heat treatment apparatus for solar cells of the present invention.

FIG. 2 is a horizontal plane cross section schematically showing an embodiment of a heat treatment apparatus for solar cells of the present invention.

FIG. 3A is a plane view showing first baffles in the present invention, FIG. 3B is a vertical front cross section schematically showing an upper part of a heat treatment apparatus for solar cells of the present invention, and FIG. 3C is a plane view showing a flow-rate adjusting plate in the present invention.

### EXPLANATION OF REFERENCE SYMBOLS

1 . . . quartz tube, 2 . . . substrate, 3 . . . heating mechanism, 4 . . . gas introduction tube, 5 . . . gas heating apparatus, 6 . . . first baffle plate, 7, 9, 11, 14 . . . holes, 8 . . . upper heater, 10 . . . flow-rate adjusting plate, 12 . . . second baffle plate, 13 . . . third baffle plate, 15 . . . fourth baffle plate, 16 . . . booster heater, 17 . . . lower heater

### BEST MODE FOR CARRYING OUT THE INVENTION

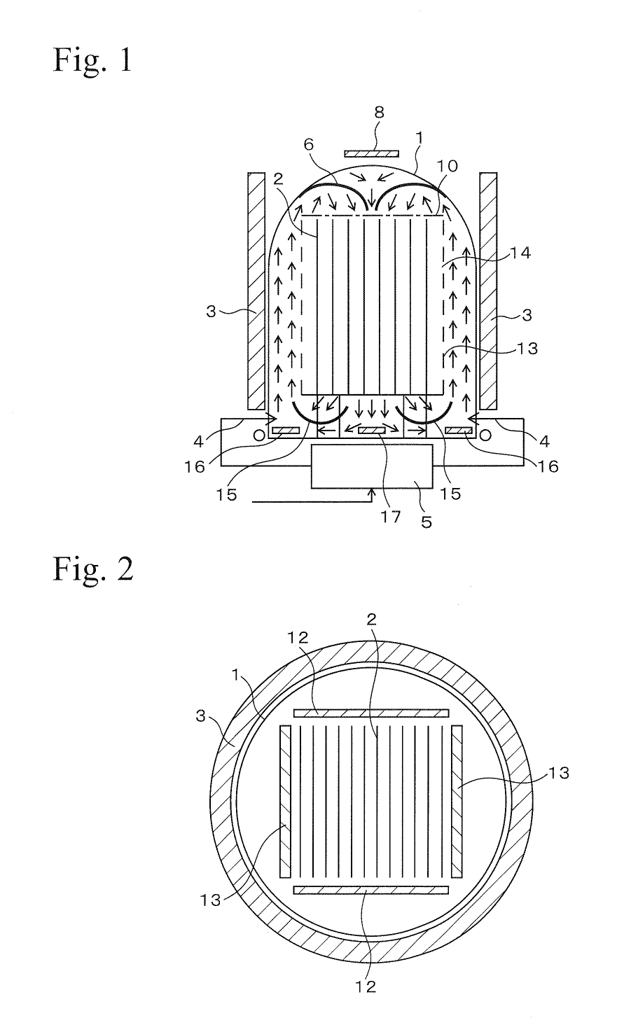

In the following, embodiments of a heating apparatus for chalcopyrite-type solar cells of the present invention will be explained in detail with reference to the drawings. FIG. 1 is a vertical front cross section schematically showing an embodiment of a heat treatment apparatus for solar cells of the present invention, and FIG. 2 is a horizontal plane cross section schematically showing an embodiment of a heat treatment apparatus for solar cells of the present invention. As shown in FIGS. 1 and 2, in the heat treatment apparatus for solar cells of the present invention, a plurality of solar cell substrates 2 is arranged in parallel at predetermined intervals in a thickness direction on a boat holder in a quartz tube 1. A heating mechanism 3 for heating atmospheric gas is arranged at an outside of the quartz tube 1, for example, so as to surround the circumference of the quartz tube 1. According to the heating mechanism 3 as constructed above, convection of atmospheric gas in the quartz tube 1 is carried out by heating.

Here, as an atmospheric gas in the quartz tube 1, selenization gas (H₂Se, hydrogen selenide gas) is introduced, for example, from a gas introduction tube 4 inserted at a lower portion of the heat treatment apparatus. It is preferable that the introduced selenization gas be previously heated by a gas heating apparatus 5 disposed in the quartz tube 1. Since the gas is introduced by heating as described above, an updraft is easily generated in the heat treatment apparatus and the convection is promoted. In addition, supplied hydrogen selenide gas is activated by heating and is supplied in a processing tank in a condition previously separated as hydrogen and selenium molecule, and therefore, an effect in which reaction time with precursor is shortened can also be obtained.

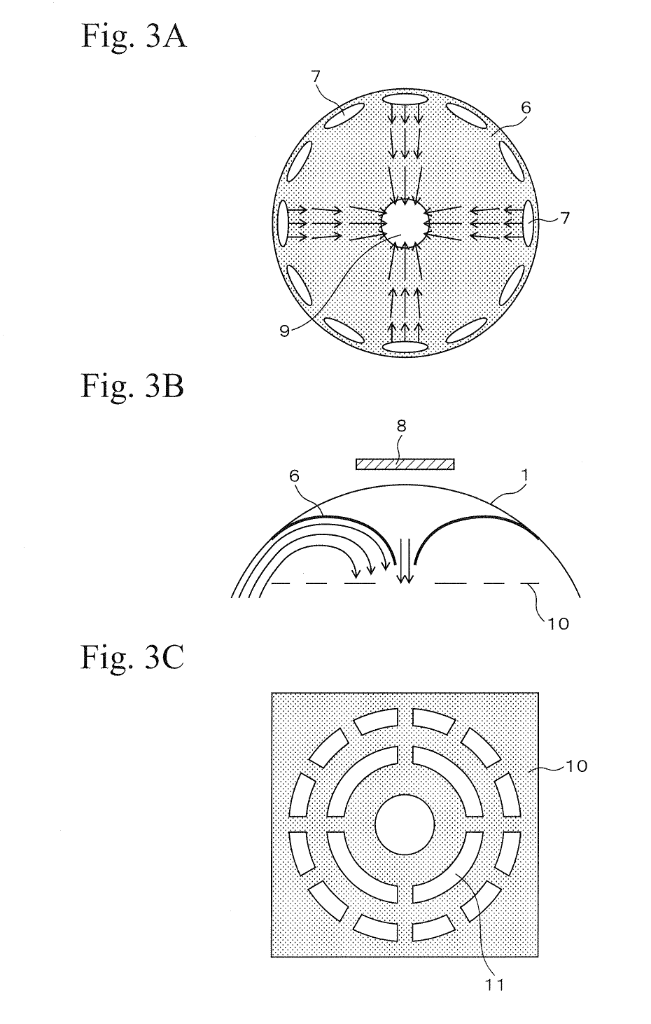

FIG. 3A is a plane view showing first baffles 6 in the present invention, FIG. 3B is a vertical front cross section schematically showing upper part of a heat treatment apparatus for solar cells of the present invention, and FIG. 3C is a plane view showing a flow-rate adjusting plate in the present invention. As shown in FIGS. 1 and 3, in the heat treatment apparatus for solar cells of the present invention, the first baffle plates 6 are arranged at an upper portion of the quartz tube 1, and heated atmospheric gas, which rises along an inner surface of the quartz tube 1, is guided from upward to the center of the substrates 2 without stagnating. The first baffle plates 6 has, for example, edges contacting with an inner surface of the quartz tube 1 and a cross section shape in which an arc is described upward from the edge toward the center and the center portion is directed downward. According to such a shape, the atmospheric gas which rises along the inner surface of the quartz tube 1 can be guided to the center of the substrates 2. Although the plane circumference of the first baffle plates 6 is circular in this embodiment, it may be a polygon, etc., so long as the atmospheric gas is guided to the center of the substrates 2.

Furthermore, the first baffle plates 6 may have holes 7 which allow the atmospheric gas that has risen near the edge thereof to pass, as shown in FIG. 3A, and the atmospheric gas that has passed through the holes 7 is heated by upper heaters 8 and is guided to the center of the substrates 2 through a center hole 9, as shown in FIGS. 1 and 3B, and therefore, a more preferable CIGS light absorbing layer can be formed.

In addition, it is preferable that a flow-rate adjusting plate 10 be provided between the substrates 2 and the first baffle plates 6, in the present invention, as shown in FIGS. 1, 3B and 3C. According to this flow-rate adjusting plate 10, the risen atmospheric gas can be uniformly guided on the substrates 2 by optionally setting the pattern of holes 11.

Furthermore, it is preferable that second baffle plates 12 be arranged between side surfaces of the substrates 2 and the heating mechanism 3 so as to be separated from the substrates 2 and the heating mechanism 3 in the present invention. According to this composition, the rising of heated atmospheric gas along the inner surface of the quartz tube 1 is promoted, the atmospheric gas is prevented from falling from clearances between each substrate during the rising, and moreover, the temperature differences between the center portion and near the side surfaces on the substrate is reduced by blocking off direct radiation of the heating mechanism 3 at the side surfaces of the substrates.

In addition, it is preferable that third baffle plates 13 be provided so as to sandwich a plurality of the substrates 2 from a thickness direction in the present invention. These third baffle plates 13 can block off direct radiation of the heating mechanism 3 to the outermost substrates in a thickness direction in a plurality of the substrates 2, and temperature differences between the outermost substrates and the second outermost or subsequent substrates can be reduced. However, since heating due to radiation is blocked by covering the entire circumference of the substrates 2 using the second baffle plates 12 and the third baffle plates 13, it is feared that the capacity of the heater is insufficient and the desired temperature profile is not obtained. Therefore, temperature control utilized for the direct radiation can be carried out by opening holes 14 having freely selected patterns on the third baffle plates 13.

Furthermore, it is preferable that fourth baffle plates 15 be provided at a lower portion of the substrates 2 in the present invention. The fourth baffle plates 15 has a cross section shape in which an arc is described downward from the center toward the edge and the edge is directed to an inner surface of the quartz tube 1, as shown in FIG. 1. According to such a shape, the atmospheric gas which falls between the substrate 2 can be guided to the inner surface of the quartz tube 1, and the convection of the atmospheric gas can be promoted.

It is preferable that the above first to fourth baffle plates be made from opaque quartz which is not penetrated by infrared light, in order to have selenium resistance at a high temperature and block off the direct radiation by the heating mechanism.

In addition, it is preferable that booster heaters 16 be arranged at a lower portion of an inner surface of the quartz tube 1 in the present invention. According to this composition, the rising of the atmospheric gas along the inner surface of the quartz tube 1 is promoted by further heating the atmospheric gas at the lower portion of the inner surface of the quartz tube 1, and the convection of the atmospheric gas can be further improved. In addition, in order to further promote the convection of the atmospheric gas which falls between the substrates 2 to the inner surface of the quartz tube 1, a hole is provided at a center portion of the above fourth baffle plates 15, and after heating the atmospheric gas that has passed through this hole by a lower heater 17, the atmospheric gas may be guided to the booster heater 16.

The chalcopyrite-type solar cell can be suitably produced by using the above heat treatment apparatus of the present invention. As a production method of this heat treatment apparatus, a production method comprising a precursor formation process in which a precursor including Cu, In, and Ga is formed on a back surface electrode layer formed on a substrate by sputtering, a selenization process in which a CIGS light absorbing layer is formed by heat-treating the precursor formed substrate under H₂Se gas atmosphere, a buffer layer formation process in which an n-type buffer layer is formed on the CIGS light absorbing layer, and a transparent electrode formation process in which a transparent electrode layer is formed on the buffer layer, can be mentioned.

The selenization process of the CIGS light absorbing layer using the heat treatment apparatus of the present invention will be explained in more detail. H₂Se gas is caused to flow at a predetermined flow rate from a gas introduction tube 4 for a predetermined term, while a decompression condition in the heat treatment apparatus is maintained at 50 to 95 kPa by actuation of an exhaust mechanism (not shown), and this is a first selenization process. In this case, it is desirable that H₂Se gas heated to about 100 to 200° C. in a pre-heating room be supplied in the apparatus, in addition to operation of the booster heater. As a result, an updraft can be positively generated from a bottom portion of the apparatus, circulation of the atmosphere is promoted with the effect of the baffle plates, and an effect in which temperatures of the substrates are made uniform can be obtained.

Next, after introduction of the H₂Se gas, the internal temperature is raised to 250 to 450° C. by the heating mechanism 3, while the decompression condition is maintained at 50 to 95 kPa. Then, the H₂Se gas is caused to flow at a predetermined flow rate from the gas introduction tube 4 for a predetermined period under conditions in which these temperature conditions and pressure conditions are maintained, and this is a second selenization process. According to this process, a Se component is taken in the light absorbing layer precursor having a layered structure in which an In layer and a Cu—Ga layer are formed on the substrates 2 while diffusing each component of In, Cu, and Ga. It is desirable that the period of this process be, for example, about 10 to 120 minutes.

In the second selenization process too, the circulation of the atmosphere is promoted by the effects of the baffle plates and the updraft generated due to operation of the booster heater and supplying of the pre-heated gas, and in order to obtain the effect in which the substrate temperature is made uniform, in particular during temperature rising, a period for making uniform the substrate temperature is shortened. Additionally, the gas previously decomposed into hydrogen and selenium molecules is supplied by setting the pre-heating temperature to be over 160° C., which is a decomposition temperature of the H₂Se gas, and as a result, the Se component in the precursor that is taken up is activated, and the effect that shortens a period for the selenization is anticipated. Furthermore, the flow of the atmospheric gas including selenium to the each substrate surface is made uniform by the effect of the baffle plates, and therefore, an amount of Se in the precursor is made uniform.

Next, the internal temperature is heated to about 500 to 650° C. by the heating mechanism 3, while the decompression condition is maintained at 50 to 95 kPa. Then, this condition is maintained for about 10 to 120 minutes, and this is the third selenization process. According to this process, the light absorbing layer precursor made uniform by the above diffusion of each component of In, Cu and Ga and taking the Se component in is crystallized and an internal membrane structure is stably reconfigured. Subsequently, after the heating temperature due to the heating mechanism 3 is gradually decreased and decreases to room temperature, the substrates 2, in which the light absorbing layer was formed by the first selenization process to the third selenization process, are taken out, and therefore, a CIGS light absorbing layer is completed.

In the third selenization process too, the internal circulation is promoted by the effect of the booster heater and the baffle plates, and as a result, crystallization and reconfiguration of each component are made uniform, the uniform CIGS light absorbing layer is formed, and therefore, the solar cell characteristics are made uniform.

1. A heat treatment apparatus for a selenization process or a sulphurization process carried out when forming a light absorbing layer in a chalcopyrite-type solar cell, comprising:
a quartz tube in which a plurality of solar cell substrates is arranged in parallel at predetermined intervals in a thickness direction,
a heating mechanism for heating atmospheric gas, which is arranged at outside of the quartz tube, and
first baffle plates arranged upward of the substrates, in which heated atmospheric gas which rises along an inner surface of the quartz tube is guided from upward to the center of the substrates.

2. The heat treatment apparatus for chalcopyrite-type solar cells, according to claim 1, further comprising second baffle plates arranged between side surfaces of the substrates and the heating mechanism so as to be separated from the substrates and the heating mechanism, wherein the second baffle plates promote the rising of heated atmospheric gas along the inner surface of the quartz tube, and block direct radiation of the heating mechanism at the side surfaces of the substrates.

3. The heat treatment apparatus for chalcopyrite-type solar cells, according to claim 1, further comprising booster heaters arranged at a lower portion of an inner surface of the quartz tube, wherein the booster heaters promote rising of heated atmospheric gas along the inner surface of the quartz tube.

4. The heat treatment apparatus for chalcopyrite-type solar cells, according to claim 1, further comprising a gas heating mechanism for preheating atmospheric gas introduced into the quartz tube.
